(19) United States
(12) Patent Application Publication
(10) Pub. No.: US 2005/0202686 A1
(43) Pub. Date: Sep. 15, 2005

(54) Method of manufacturing semiconductor device

(76) Inventors: Kazuo Saki, Kanagawa (JP); Shinji Mori, Kanagawa (JP); Takashi Shimizu, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/884,987

(22) Filed: Jul. 7, 2004

(30) Foreign Application Priority Data
Mar. 15, 2004 (JP) 2004-073189

(51) Int. Cl. H01L 21/31; H01L 21/336; H01L 21/3205; H01L 21/302

(52) U.S. Cl. 438/783; 438/786; 438/591; 438/585; 438/513; 438/197

(57) ABSTRACT

A method of manufacturing a semiconductor device according to an embodiment of the present invention comprises forming a semiconductor element on a semiconductor substrate, forming a silicon oxide film containing nitrogen on the semiconductor element and injecting heavy hydrogen into the silicon oxide film containing nitrogen.

### CROSS-REFERENCE TO RELATED APPLICATIONS

This application claims the benefit of priority under 35USC §119 to Japanese Patent Application No. 2004-073189, filed on Mar. 15, 2004, the entire contents of which are incorporated herein by reference herein.

### BACKGROUND OF THE INVENTION

1. Field of the Invention

The present invention relates to a method of manufacturing a semiconductor device.

2. Background Art

In recent years, thinning of a gate insulating film is accelerated for micropatterning of an element and improvement of transistor characteristics.

The thinning of the gate insulating film occurs the following serious problem, that is, deterioration of NBTI (Negative Bias Temperature Instability) characteristics representing aging of the threshold voltage of a transistor. The NBTI characteristics are one of characteristics of the reliabilities of the gate insulating film.

Micropatterning of the element generates a crystal defect in an element region in the substrate to adversely affect the device characteristics as junction leakage in, e.g., a PN junction.

It is known that the deterioration of the NBTI characteristics is triggered by separation of hydrogen present in the gate insulating film. More specifically, hydrogen which terminates dangling bonds (unattached hands) in the gate insulating film is separated to generate dangling bonds, thereby causing deterioration of the NBTI characteristics.

In order to improve the NBTI characteristics, two roughly classified points are known. As one of the two points, hydrogen which terminates dangling bonds is replaced with heavy hydrogen which is separated more difficultly than hydrogen. As the other, for the sake of terminating as many dangling bonds as possible by heavy hydrogen, it is prevented that hydrogen generated in various processes (post-processes) after the gate insulating film is formed is diffused into the gate insulating film to terminate dangling bonds in the gate insulating film.

On the other hand, similar to a defect (dangling bonds) in an element region in a substrate, in a conventional art, dangling bonds terminated by hydrogen are advantageously terminated by heavy hydrogen having strong bonding force with silicon (Si).

As methods of supplying heavy hydrogen to terminate dangling bonds in a gate insulating film or an element region, a method of directly supplying heavy hydrogen by heavy hydrogen annealing/heavy water annealing or the like and a method of supplying heavy hydrogen by using a film containing heavy hydrogen as a diffusion source are known. When the latter method is used, i.e., heavy hydrogen is supplied by using a film containing heavy hydrogen as a diffusion source, the film serving as the diffusion source and containing a large amount of hydrogen is advantageous to terminate a large number of dangling bonds.

As a method of suppressing hydrogen generated in various processes (post-processes) after a gate insulating film is formed from being diffused into the gate insulating film, a method of injecting a large amount of heavy hydrogen into an interlayer insulation film covering the gate insulating film and causing the heavy hydrogen in the interlayer insulation film to block hydrogen from being diffused from the upper layer of the interlayer insulation film to the lower layer thereof, is known.

However, in the conventional art, heavy hydrogen cannot be sufficiently injected into the diffusion layer of heavy hydrogen or the interlayer insulation film covering the gate insulating film.

For this reason, a large number of unterminated dangling bonds are still present in the gate insulating film or the element region. In addition, dangling bonds in the gate insulating film are frequently terminated by hydrogen generated in the various processes performed after the gage insulating film.

### BRIEF SUMMARY OF THE INVENTION

A method of manufacturing a semiconductor device according to an embodiment of the present invention comprises forming a semiconductor element on a semiconductor substrate, forming a silicon oxide film containing nitrogen on the semiconductor element and injecting heavy hydrogen into the silicon oxide film containing nitrogen.

A method of manufacturing a semiconductor device according to an embodiment of the present invention comprises forming an element isolation film by a silicon oxide film containing nitrogen on a semiconductor substrate, injecting heavy hydrogen into the element isolation film and forming a semiconductor element in an element region on the semiconductor substrate partitioned by the element isolation film.

### BRIEF DESCRIPTION OF THE DRAWINGS

FIGS. 1A to 1C are sectional views of manufacturing steps for explaining a method of manufacturing a semiconductor device according to an embodiment of the present invention.

FIGS. 2A to 2C are sectional views of manufacturing steps following the steps in FIGS. 1A to 1C.

FIGS. 3A and 3B are sectional views of manufacturing steps following the steps in FIGS. 2A to 2C.

FIGS. 4A and 4B are sectional views of manufacturing steps following the steps in FIGS. 3A and 3B.

FIG. 5 is a sectional view of a manufacturing step following the steps in FIGS. 4A and 4B.

FIG. 6 is a sectional view of a manufacturing step following the step in FIG. 5.

FIG. 7A is a graph for explaining a distribution of heavy hydrogen and nitrogen atoms in a silicon oxynitride film.

FIG. 7B is a graph for explaining a distribution of heavy hydrogen in a silicon oxide film.

### DETAILED DESCRIPTION OF THE INVENTION

An embodiment of the present invention will be described below with reference to the accompanying drawings.

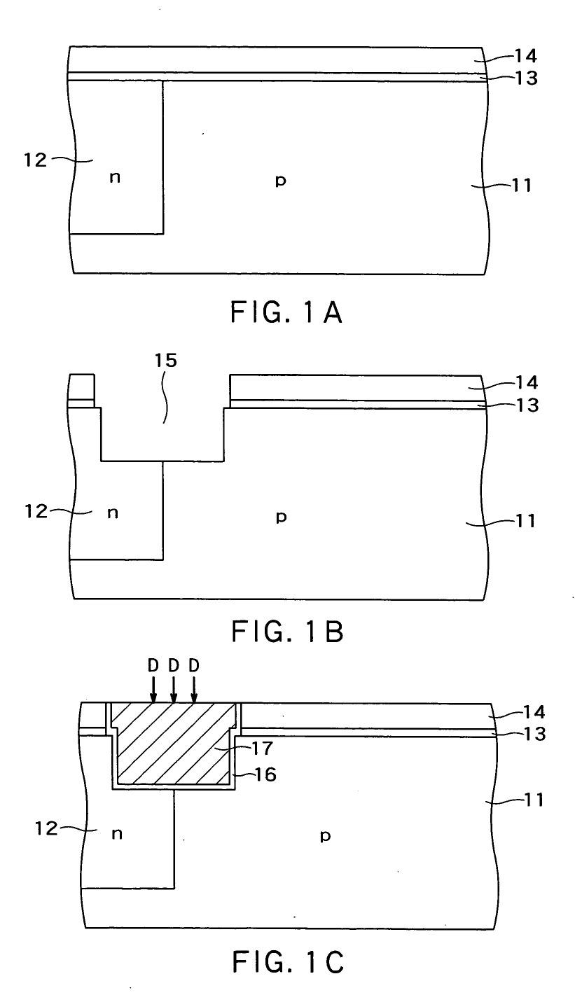

FIGS. 1A to 6 are sectional views of manufacturing steps for explaining a method of manufacturing a semiconductor device according to an embodiment of the present invention.

As shown in FIG. 1A, impurity ions such as phosphorous ions are injected into a p-type silicon substrate 11 to form an n-type well 12.

A silicon oxide film 13 having, e.g., a thickness of 8 nm is formed on the silicon substrate 11 by thermal oxidation.

A silicon nitride film 14 having, e.g., a thickness of 150 nm is formed on the silicon oxide film 13 by a LPCVD (Low Pressure Chemical Vapor Deposition) method.

As shown in FIG. 1B, a photoresist is applied onto the silicon nitride film 14 and baked to form a photoresist film (not shown). Thereafter, the photoresist film is patterned by using photolithographic technique.

By using the patterned photoresist film as a mask, the silicon nitride film 14, the silicon oxide film 13, and the silicon substrate 11 are sequentially etched by an etching technique such as a reactive ion etching (RIE) to form a groove 15.

As shown in FIG. 1C, a silicon oxide film 16 is formed on the entire surface of the substrate by thermal oxidation, and a silicon oxynitride film 17 is deposited on the silicon oxide film 16 using an LPCVD method.

A chemical mechanical polishing (CMP) process is used to polish the silicon oxide film 16 and the silicon oxynitride film 17 on the silicon nitride film 14, so that the substrate surface is flattened as shown in FIG. 1C.

The substrate in this state is heat-treated in an atmosphere including a heavy hydrogen gas or a heavy hydrogen steam to inject heavy hydrogen into the silicon oxynitride film 17 as shown in FIG. 1C. Nitrogen atoms being present in the silicon oxynitride film 17 cause a large amount of heavy hydrogen to be injected into the silicon oxynitride film 17.

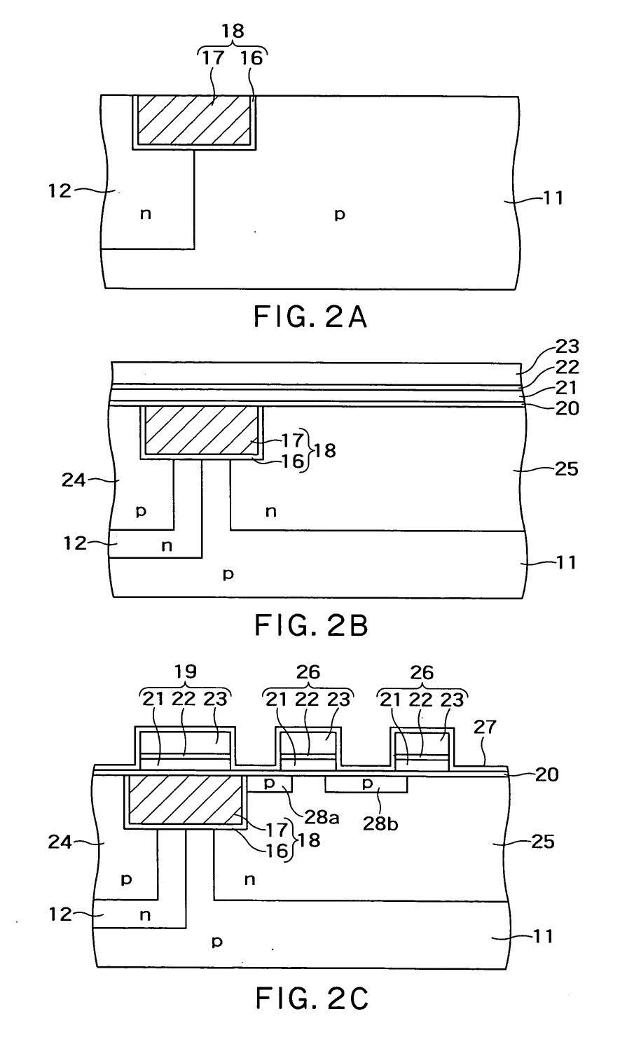

The silicon oxide film 13 and the silicon nitride film 14 on the silicon substrate 11, a part of the silicon oxide film 16 above the interface between the silicon substrate 11 and the silicon oxide film 13, and the silicon oxynitride film 17 containing heavy hydrogen above the interface are removed by using a phosphoric acid solution, a hydrogen fluoride aqueous solution, and the like to form an element isolation film 18 containing heavy hydrogen as shown in FIG. 2A. Since a large amount of heavy hydrogen is injected into the element isolation film 18, the element isolation film 18 is effectively used as a diffusion source of heavy hydrogen.

As shown in FIG. 2B, an impurity such as boron is injected into the n-type well 12 to form a p-type well 24. An impurity such as phosphorous is injected into the silicon substrate 11 to form an n-type well 25 isolated from the n-type well 12.

After a silicon oxide film is formed by thermal oxidation, a plasma nitriding process and reduced-pressure oxygen annealing are performed to form a silicon oxynitride film (gate insulating film) 20. The thickness of the gate insulating film 20 is, e.g., 1.7 nm as a physical thickness. As the gate insulating film, not only a silicon oxynitride film, but also a silicon oxide film/hafnium oxide film or the like may be used.

On the gate insulating film 20, a polycrystalline silicon film 21 in which an impurity such as phosphorous is doped, a tungsten silicide film 22 to which silicon is added, and a silicon nitride film 23 serving as a cap layer are sequentially deposited.

A pattern (not shown) constituted by a photoresist film is formed on the silicon nitride film 23 by a photolithographic technique.

As shown in FIG. 2C, the silicon nitride film 23, the tungsten silicide film 22, and the polycrystalline silicon film 21 are sequentially plasma-ion-etched by using the pattern as a mask to form a connection wiring electrode 19 and a gate wiring electrode 26.

The side walls of the connection wiring electrode 19 and the gate wiring electrode 26 are oxidized by thermal oxidation to form an oxide film (not shown) having a thickness of, e.g., 2 nm.

Impurity ions such as boron ions are injected into the surface of the silicon substrate 11 by a known ion injection method using the connection wiring electrode 19 and the gate wiring electrode 26 as masks. In this manner, a p-type impurity diffusion region (drain region) 28a and a p-type impurity diffusion region (source region) 28b are formed in the surface region of the silicon substrate 11. More specifically, a field-effect transistor including the drain region 28a, the source region 28b, the gate insulating film 20, and the gate wiring electrode 26 is formed. This field-effect transistor corresponds to, e.g., a semiconductor element. This semiconductor element includes not only a field-effect transistor (MOS transistor) but also a bipolar transistor, a resistor, a capacitor, and the like. The drain region 28a is electrically connected to the polycrystalline silicon film 21 and the tungsten silicide film 22 in the connection wiring electrode 19 in a region (not shown).

By using, e.g., an LPCVD method, a silicon oxide film 27 having a thickness of, e.g., 10.0 nm is formed on the entire surface of the substrate (the side wall and the upper surface of the wiring electrode 19, 26, and the surface of the gate insulating film 20).

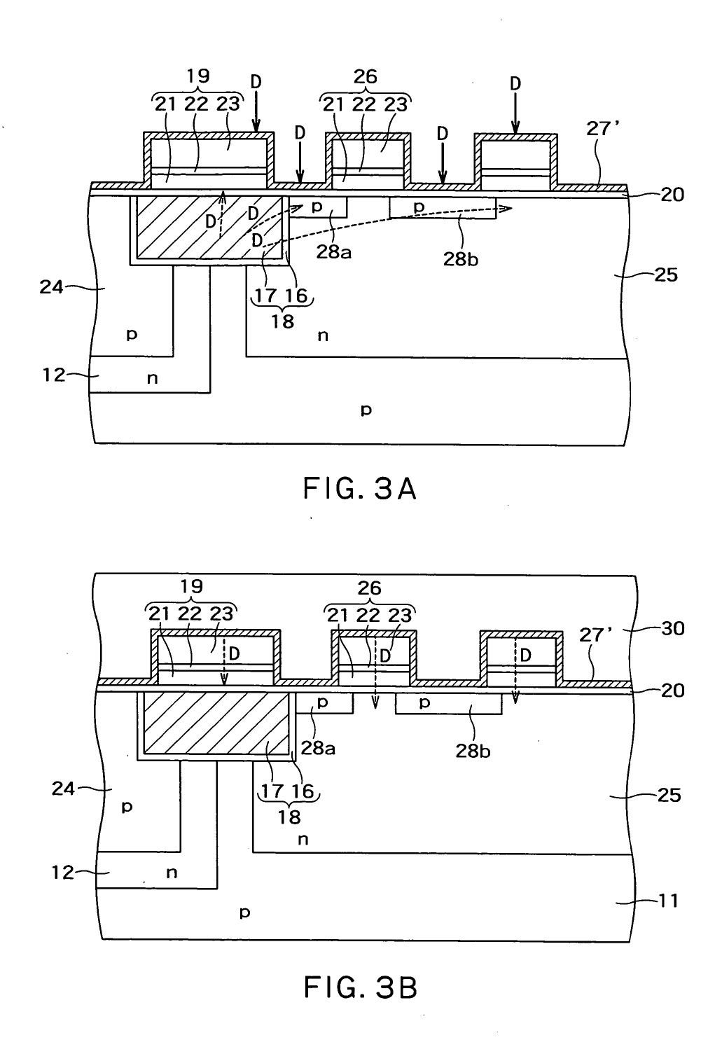

As shown in FIG. 3A, nitrogen is injected into the silicon oxide film 27 formed on the side wall and upper surface of the wiring electrode 19,26 or the like by a plasma nitriding process or the like depending on a plasma nitriding method to form a silicon oxynitride film 27′. As a method of injecting nitrogen into the silicon oxide film 27, not only a plasma nitriding technique, but also a thermal process such as NH₃ nitriding and NO nitriding depending on a thermal nitriding method may be used. The silicon oxynitride film may be formed such that nitrogen is injected into the silicon oxide film simultaneously with deposition of the silicon oxide film by the LPCVD method.

After the silicon oxynitride film 27′ is formed in this manner, heat annealing at a temperature of about 900° C. is performed in an atmosphere including a heavy hydrogen gas to inject heavy hydrogen into the silicon oxynitride film 27′ as shown in FIG. 3A. Since a large amount of heavy hydrogen is injected into the silicon oxynitride film 27′, the silicon oxynitride film 27′ is effective as a heavy hydrogen diffusion source, and effectively blocks hydrogen generated in the post-process (e.g., CVD process) from passing through the silicon oxynitride film 27′ and reaching the gate insulating film 20.

In the above heat annealing, as shown in FIG. 3A, heavy hydrogen contained in the element isolation film 18 is diffused. The diffused heavy hydrogen reaches the element region in the substrate (region in the substrate except for a region in which the element isolation film 18 is formed) or the gate insulating film 20 to terminate dangling bonds in the element region or the gate insulating film (to correct defects). In the above heat annealing, impurities in the drain region 28a and the source region 28b are activated. More specifically, when the heat annealing is performed once, diffusion of heavy hydrogen and activation of impurities can be performed at once. When the temperature of the heat annealing is high, diffusion efficiency is more improved. However, the temperature of the heat annealing are regulated by various process conditions. For example, when the heat annealing is performed after a wiring forming process is performed, the temperature is regulated to the range of 200° C. to 300° C.

In plasma etching (see FIG. 2C) performed when the gate wiring electrode 26 is formed, damage such as lattice defects is induced in the gate insulating film 20 near the lower portion of the side wall of the gate wiring electrode 26. The damage is corrected in the above heat annealing.

As shown in FIG. 3B, a boron-and-phosphorous-doped oxide film (BPSG film) 30 is deposited on the entire surface of the substrate as an interlayer insulation film by using a CVD method or the like.

The substrate in this state is subjected to heat annealing at 900° C. to diffuse heavy hydrogen in the silicon oxynitride film 27′ containing heavy hydrogen. At this time, the remaining heavy hydrogen in the element isolation film 18 is also diffused in some degree.

In this case, since the BPSG film 30 is formed on the silicon oxynitride film 27′ containing heavy hydrogen, heavy hydrogen is slightly efficiently diffused toward the substrate surface in comparison with a case in which the BPSG film 30 is not formed.

The diffused heavy hydrogen reaches the gate insulating film 20 or the inside of the silicon substrate to terminate dangling bonds in the gate insulating film 20 and dangling bonds in the element region in the silicon substrate.

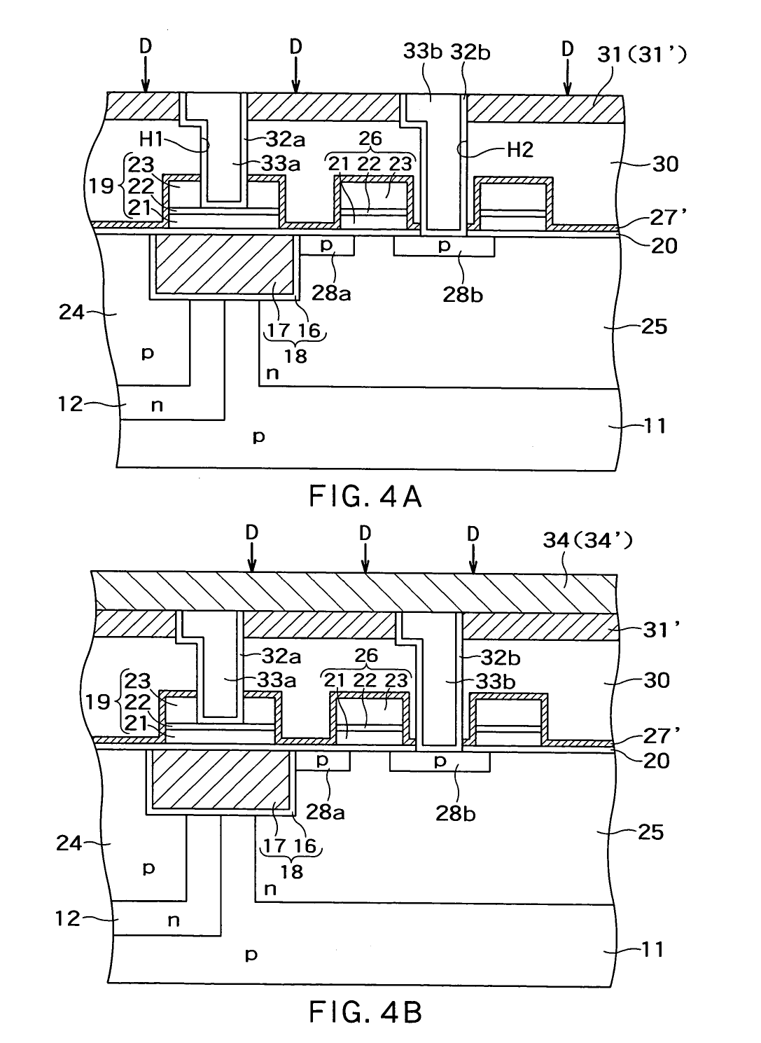

As shown in FIG. 4A, a CVD method is performed in a gas atmosphere containing tetraethoxy silane (TEOS) to form a silicon oxide film 31 as an interlayer insulation film on the BPSG film 30. In the formation of the silicon oxide film 31, hydrogen is generated from a gas material and diffused. However, the heavy hydrogen remaining in the silicon oxynitride film 27′ blocks the diffused hydrogen from reaching the gate insulating film 20, i.e., dangling bonds in the gate insulating film 20 from being terminated by hydrogen. More specifically, the heavy hydrogen remaining in the silicon oxynitride film 27′ blocks hydrogen from passing through the silicon oxynitride film 27′.

Nitrogen is injected into the silicon oxide film 31 by a plasma nitriding process or the like to form a silicon oxynitride film 31′. A plasma process is performed in an atmosphere including a heavy hydrogen gas to inject heavy hydrogen into the silicon oxynitride film 31′.

A pattern (not shown) constituted by a photoresist film is formed on the silicon oxynitride film 31′, and the silicon oxynitride film 31′ containing heavy hydrogen and the BPSG film 30 are sequentially etched by using the pattern to form a hole H1 reaching the tungsten silicide film 22 in the connection wiring electrode 19 and a hole H2 reaching the source region 28b.

Barrier metal films 32a and 32b consisting of titanium are formed on the surfaces in the holes H1 and H2, respectively. Plugs 33a and 33b consisting of tungsten are formed to be buried inside the barrier metal films 32a and 32b, respectively.

As shown in FIG. 4B, a CVD method is performed in a gas atmosphere including TEOS to form a silicon oxide film 34 as an interlayer insulation film on the entire surface of the substrate. In the formation of the silicon oxide film 34, hydrogen is generated from a gas material and diffused. However, the heavy hydrogen remaining in the silicon oxynitride film 31′ below the silicon oxide film 34 blocks the hydrogen from reaching the gate insulating film 20.

Nitrogen is injected into the silicon oxide film 34 by a plasma nitriding process or the like to form a silicon oxynitride film 34′. A plasma process is performed in an atmosphere including a heavy hydrogen gas to inject heavy hydrogen into the silicon oxynitride film 34′ as shown in FIG. 4B.

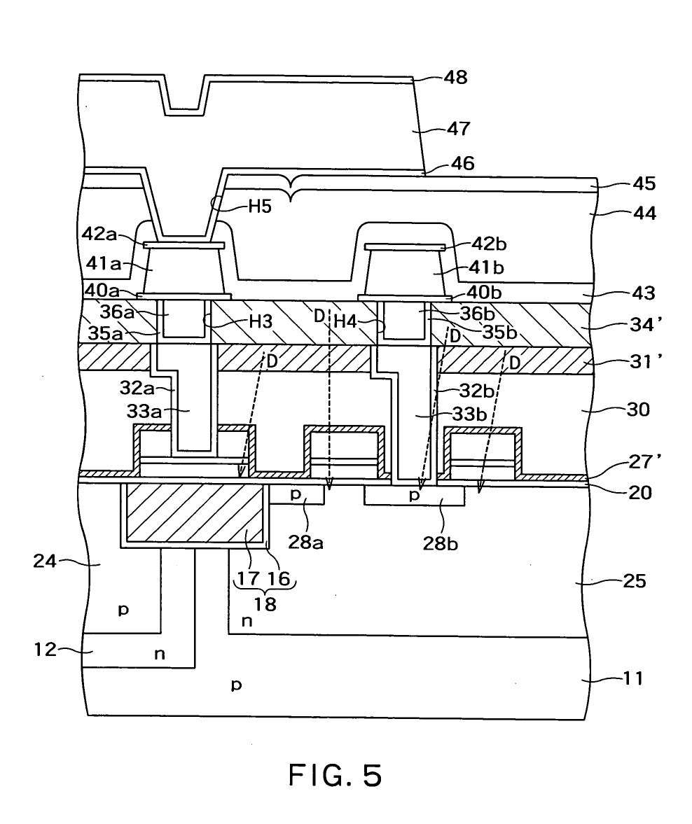

As shown in FIG. 5, a photo-mask pattern (not shown) is formed on the silicon oxynitride film 34′ in which heavy hydrogen is injected. The silicon oxynitride film 34′ is etched by using the photo-mask pattern to form holes H3 and H4 at positions on the plugs 33a and 33b, respectively. Barrier metal films 35a and 35b consisting of titanium nitride are formed on surfaces in the holes H3 and H4, respectively. Plugs 36a and 36b consisting of tungsten are formed to be buried inside the barrier metal films 35a and 35b, respectively.

Ti/TiN films 40a and 40b obtained by stacking a titanium film and a titanium nitride film to cover the barrier metal film 35a and the plug 36a and the barrier metal film 35b and the plug 36b are formed by using a sputtering method or the like.

Al—Cu films 41a and 41b obtained by adding copper as an impurity to aluminum are formed on the Ti/TiN films 40a and 40b by a sputtering method or the like, respectively.

Ti/TiN film 42a and 42b are formed on the Al—Cu films 41a and 41b by a sputtering method or the like, respectively.

A CVD method is performed by using TEOS as a gas material to form a silicon oxide film 43 as an interlayer insulation film to cover the entire surface of the substrate. Although hydrogen is generated from the gas material and diffused in the formation of the silicon oxide film 43, the heavy hydrogen in the silicon oxynitride film 34′ or the like located below the silicon oxide film 43 blocks the hydrogen from reaching the gate insulating film 20.

An SAUSG (Sub Atmospheric Undoped Silicate Glass) film 44 is formed on the entire surface of the substrate, and a silicon oxide film 45 is formed by using TEOS as a gas material. Although hydrogen is generated from the gas material and diffused in the formation of the silicon oxide film 45, the heavy hydrogen in the silicon oxynitride films 34′ and 31′ located below the silicon oxide film 45 blocks the hydrogen from reaching the gate insulating film 20.

A pattern (not shown) constituted by a photoresist film is formed on the silicon oxide film 45, and the silicon oxide film 45 and the SAUSG film 44 are sequentially etched by RIE or the like using the pattern to form a hole H5 to the Ti/TiN film 42a.

A Ti/TiN film 46 is formed on the surface in the hole H5 and the silicon oxide film 45, and an Al—Cu film 47 and a TiN film 48 are sequentially formed on the Ti/TiN film 46.

The substrate in this state is subjected to heat annealing. In this manner, the heavy hydrogen contained in the silicon oxynitride films 31′ and 34′ is diffused as shown in FIG. 5, and the remaining heavy hydrogen in the element isolation film 18 and the silicon oxynitride film 27′ is diffused. The heavy hydrogen diffused from the silicon oxynitride films 31′ and 34′ reaches the gate insulating film 20 and the element region in the silicon substrate 11 to terminal dangling bonds present in the gate insulating film 20 and the element region.

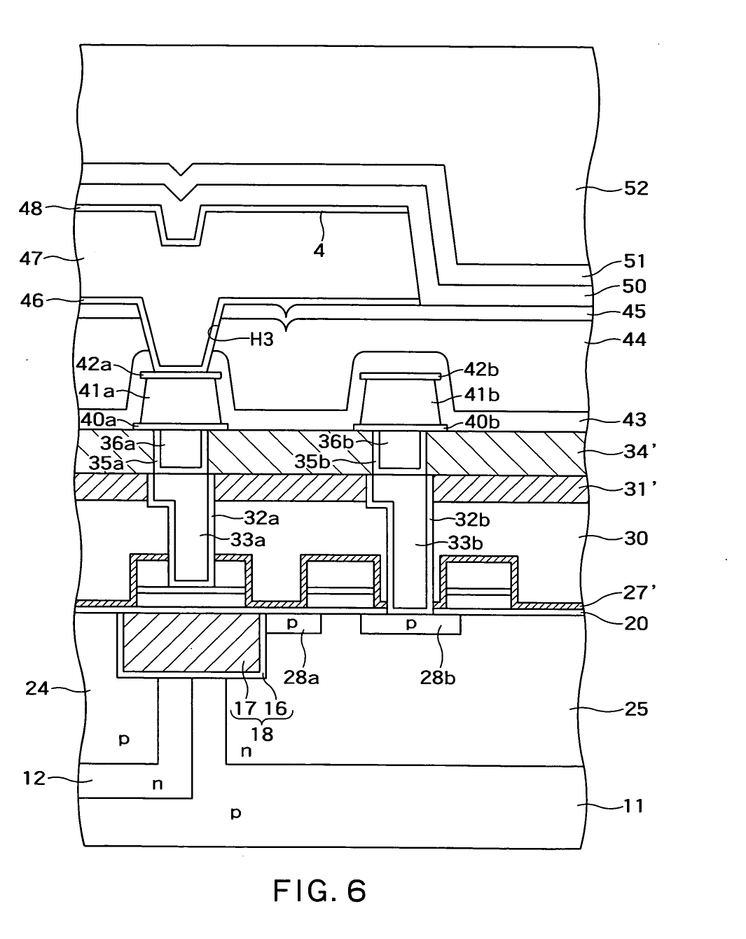

As shown in FIG. 6, a CVD method is performed to the entire surface of the substrate by using TEOS as a gas material to form a silicon oxide film 50.

A silicon nitride film 51 is formed on the silicon oxide film 50 by using a CVD method or the like.

Thereafter, a polyimide resin is applied onto the silicon nitride film 51 and sintered to form a polyimide resin film 52.

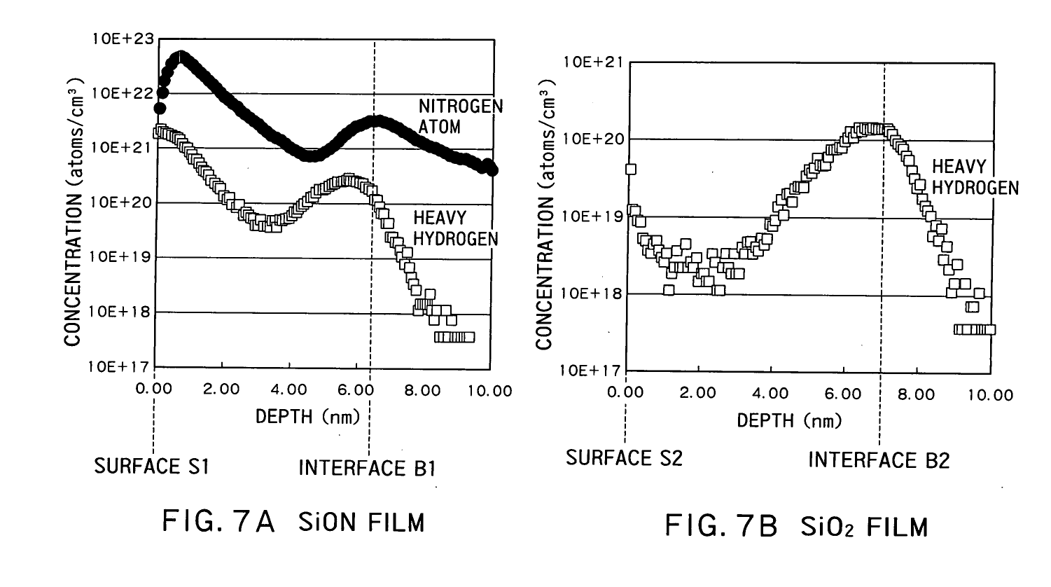

FIGS. 7A and 7B are graphs created on the basis of unique experiment results obtained by the present inventors.

More specifically, FIG. 7A is a graph showing a result obtained by the following processes. That is, a silicon oxynitride film is formed on a semiconductor substrate, the substrate in this state is heat-annealed in a gas atmosphere including heavy hydrogen to inject heavy hydrogen in the silicon oxynitride film, and distributions of heavy hydrogen and nitrogen atoms are analyzed by secondary ion mass spectrometry (SIMS).

FIG. 7B is a graph showing a result obtained by the following processes. That is, after heavy hydrogen is injected by the same method as that in FIG. 7A using a silicon oxide film in place of a silicon oxynitride film, a distribution of heavy hydrogen is analyzed by the SIMS.

Positions indicated by surfaces S1 and S2 in FIGS. 7A and 7B correspond to the surfaces of the silicon oxynitride film and the silicon oxide film, respectively.

A position indicated by an interface B1 in FIG. 7A corresponds to an interface between the silicon oxynitride film and the semiconductor substrate. A position indicated by an interface B2 in FIG. 7B corresponds to an interface between the silicon oxide film and the semiconductor substrate.

Although scales in the abscissa directions (depths from the surfaces) in FIGS. 7A and 7b are equal to each other, a scale in the ordinate direction (concentration) is larger in FIG. 7B than in FIG. 7A to make a change in concentration of heavy hydrogen clear.

As shown in FIG. 7B, when a silicon oxide film is used, a concentration of heavy hydrogen in the silicon oxide film is about 1.0×10¹⁸ to 1.0×10²⁰ (atoms/cm³). In contrast to this, when a silicon oxynitride film is used, a concentration of heavy hydrogen in the silicon oxynitride film is about 5.0×10¹⁹ to 2.0×10²¹ (atoms/cm³). For this reason, it is understood that the silicon oxynitride film contains heavy hydrogen the amount of which is larger than that in the silicon oxide film.

As shown in FIG. 7A, in the silicon oxynitride film, the concentration of heavy hydrogen changes almost depending on a change in concentration of nitrogen atoms. Therefore, it is understood that a film containing a large number of nitrogen atoms can make it possible to inject a large amount of heavy hydrogen in the film.

A heavy hydrogen concentrations in the element isolation film 18 and the silicon oxynitride films 27′, 31′, and 34′ after the polyimide resin film 52 shown in FIG. 6 is formed are estimated as about 10¹⁷ to 10¹⁹ (atoms/cm³) from the experiment results or the like.

As described above, according to the embodiment of the present invention, since heavy hydrogen is injected in a silicon oxynitride film containing nitrogen, a film (insulating film) containing a large amount of heavy hydrogen can be formed as a diffusion source of heavy hydrogen. A substrate is heat-annealed to diffuse heavy hydrogen in the film, so that a large number of dangling bonds can be terminated. More specifically, when a silicon oxynitride film in which heavy hydrogen is injected is used as a diffusion source, a large number of dangling bonds can be terminated in comparison with a case in which a heavy-hydrogen-doped silicon oxide film is used as a diffusion source.

According to the embodiment, as described above, a film (insulating film) containing a large amount of heavy hydrogen can be formed. For this reason, even though hydrogen is generated in a CVD process or the like after the film is formed, the heavy hydrogen present in the film effectively blocks the hydrogen from reaching a layer below the film. Therefore, dangling bonds in a gate insulating film or an element region present below the film are blocked from being terminated by hydrogen as far as possible.

As has been described above, according to the embodiment, since a large number of dangling bonds present in the gate insulating film or the element region can be terminated by heavy hydrogen, NBTI characteristics are improved, and defects in the element region are repaired.

1. A method of manufacturing a semiconductor device comprising:
forming a semiconductor element on a semiconductor substrate;
forming a silicon oxide film containing nitrogen on the semiconductor element; and
injecting heavy hydrogen into the silicon oxide film containing nitrogen.

2. The method of manufacturing a semiconductor device according to claim 1, wherein after the heavy hydrogen is injected, the semiconductor substrate is heated to diffuse the heavy hydrogen contained in the silicon oxide film containing nitrogen.

3. The method of manufacturing a semiconductor device according to claim 2, wherein a insulating film is formed on the semiconductor substrate, a gate electrode is formed on the insulating film, an impurity is implanted in a surface region of the semiconductor substrate by using the gate electrode as a mask to form source-drain regions on both the sides of a channel region, thereby forming the semiconductor element.

4. The method of manufacturing a semiconductor device according to claim 3, wherein the silicon oxide film containing nitrogen is formed on the surface of the gate electrode and the surface of the insulating film.

5. The method of manufacturing a semiconductor device according to claim 4, further comprising:
sequentially forming an interlayer insulation film and another silicon oxide film containing nitrogen on the silicon oxide film containing nitrogen;
sequentially etching the other silicon oxide film containing nitride, the interlayer insulation film, the silicon oxide film containing nitride, and the insulating film to form holes to the source-drain regions, respectively;
forming contact electrodes in the holes; and
injecting heavy hydrogen in the other silicon oxide film containing nitrogen.

6. The method of manufacturing a semiconductor device according to claim 5, wherein the semiconductor substrate is heated to diffuse heavy hydrogen contained in the other silicon oxide film containing nitrogen.

7. The method of manufacturing a semiconductor device according to claim 2, wherein a CVD method is performed by using a gas containing silicon atoms, oxygen atoms, and nitrogen atoms as a source gas to form the silicon oxide film containing nitrogen.

8. The method of manufacturing a semiconductor device according to claim 2, wherein after a silicon oxide film is formed, nitrogen is injected into the silicon oxide film to form the silicon oxide film containing nitrogen.

9. The method of manufacturing a semiconductor device according to claim 8, wherein nitrogen is injected into the silicon oxide film by using a plasma nitriding method or a thermal nitriding method.

10. The method of manufacturing a semiconductor device according to claim 2, wherein heat treatment is performed to the semiconductor substrate in an atmosphere including a heavy hydrogen gas or a heavy hydrogen steam to inject heavy hydrogen into the silicon oxide film containing nitrogen.

11. The method of manufacturing a semiconductor device according to claim 2, wherein a plasma process is performed in a heavy hydrogen gas atmosphere to inject heavy hydrogen into the silicon oxide film containing nitrogen.

12. A method of manufacturing a semiconductor device, comprising:
forming an element isolation film by a silicon oxide film containing nitrogen on a semiconductor substrate;
injecting heavy hydrogen into the element isolation film; and
forming a semiconductor element in an element region on the semiconductor substrate partitioned by the element isolation film.

13. The method of manufacturing a semiconductor device according to claim 12, further comprising:
heating the semiconductor substrate to diffuse heavy hydrogen contained in the element isolation film.

14. The method of manufacturing a semiconductor device according to claim 13, comprising:
etching the semiconductor substrate from the surface to the inside to form a groove;
forming a silicon oxide film containing nitrogen to cover the semiconductor substrate; and
polishing the silicon oxide film containing nitrogen on the surface of the semiconductor substrate to leave the silicon oxide film containing nitrogen in the groove;
thereby forming the element isolation film.

15. The method of manufacturing a semiconductor device according to claim 14, wherein a CVD method is performed by using a gas containing silicon atoms, oxygen atoms, and nitrogen atoms as a source gas to form the silicon oxide film containing nitrogen.

16. The method of manufacturing a semiconductor device according to claim 14, wherein after a silicon oxide film is formed, nitrogen is injected into the silicon oxide film to form the silicon oxide film containing nitrogen.

17. The method of manufacturing a semiconductor device according to claim 16, wherein nitrogen is injected into the silicon oxide film by using a plasma nitriding method or a thermal nitriding method.

18. The method of manufacturing a semiconductor device according to claim 13, wherein heat treatment is performed to the semiconductor substrate in an atmosphere including a heavy hydrogen gas or a heavy hydrogen steam to inject heavy hydrogen into the element isolation film.

19. The method of manufacturing a semiconductor device according to claim 13, wherein a plasma process is performed in a heavy hydrogen gas atmosphere to inject heavy hydrogen into the element isolation film.
